(19) United States
(12) Patent Application Publication
(10) Pub. No.: US 2026/0161098 A1
(43) Pub. Date: Jun. 11, 2026

(54) METHOD FOR MANUFACTURING SEMICONDUCTOR DEVICE

(71) Applicant: SAMSUNG ELECTRONICS CO., LTD., Suwon-si (KR)

(72) Inventor: Hyejin KIM, Suwon-si (KR)

(73) Assignee: SAMSUNG ELECTRONICS CO., LTD., Suwon-si (KR)

(21) Appl. No.: 19/289,801

(22) Filed: Aug. 4, 2025

(30) Foreign Application Priority Data
Dec. 9, 2024 (KR) 10-2024-0182016

(51) Int. Cl. G03F 7/00; G03F 1/82; H01L 21/48

(52) U.S. Cl. CPC G03F 7/70433; G03F 1/82; H10W 70/05

(57) ABSTRACT

A method for manufacturing a semiconductor device according to an embodiment includes: measuring absorbance of a photosensitive material and quantifying photosensitivity of the photosensitive material; stacking a photosensitive layer made of the photosensitive material; manufacturing an exposure mask or setting exposure amounts depending on positions of the photosensitive layer based on the photosensitivity of the photosensitive material; and exposing the photosensitive layer using the exposure mask or using the set exposure amounts.

### CROSS-REFERENCE TO RELATED APPLICATION

This application claims priority to and the benefit of Korean Patent Application No. 10-2024-0182016 filed at the Korean Intellectual Property Office filed on Dec. 9, 2024, the entire contents of which are incorporated herein by reference.

### BACKGROUND

### 1. Field

The present disclosure relates to a method for manufacturing a semiconductor device.

### 2. Description of the Related Art

As semiconductor devices are integrated, semiconductor chips may be integrated on a semiconductor substrate.

Cavities with different depths may be formed in an insulating layer of the semiconductor substrate, semiconductor chips may be integrated in the cavities, and wiring layers of the semiconductor substrate may be electrically connected to the semiconductor chips through pad portions on the semiconductor substrate.

A photosensitive layer may be exposed for multiple times to form the cavities with different depths and grooves for forming pad portions.

When the exposure processes are performed, a production cost and a manufacturing time may increase, and manufacturing process errors caused by misalignment may be generated during the exposure processes.

### SUMMARY

The present disclosure attempts to provide a method for manufacturing a semiconductor device for reducing a production cost and a manufacturing time and reducing manufacturing process errors.

However, tasks to be solved by embodiments of the present disclosure may not be limited to the above-described task, and may be extended in various ways within a range of technical scopes included in the present disclosure.

An embodiment of the present disclosure provides a method for manufacturing a semiconductor device including: measuring absorbance of a photosensitive material and quantifying photosensitivity of the photosensitive material; manufacturing an exposure mask based on the photosensitivity of the photosensitive material; stacking a photosensitive layer made of the photosensitive material; and exposing the photosensitive layer using the exposure mask.

Another embodiment of the present disclosure provides a method for manufacturing a semiconductor device including: measuring absorbance of a photosensitive material and quantifying photosensitivity of the photosensitive material; stacking a photosensitive layer made of the photosensitive material; based on the photosensitivity of the photosensitive material, setting exposure amounts depending on positions of the photosensitive layer; and exposing the photosensitive layer using the set exposure amounts.

Another embodiment of the present disclosure provides a method for manufacturing a semiconductor device including: measuring absorbance of a photosensitive material and quantifying photosensitivity the photosensitive material; stacking a photosensitive layer made of the photosensitive material; manufacturing an exposure mask based on the quantified photosensitivity of the photosensitive layer or setting exposure amounts depending on positions of the photosensitive layer based on the quantified photosensitivity of the photosensitive material; and exposing the photosensitive layer using the exposure mask or using the set exposure amounts.

Another embodiment of the present disclosure provides a method for manufacturing a semiconductor device including: measuring absorbance of a photosensitive material and quantifying photosensitivity of the photosensitive material; forming a photosensitive layer made of the photosensitive material; simultaneously exposing a plurality of regions of the photosensitive layer, such that, based on the photosensitivity of the photosensitive material, light energy irradiated on the plurality of regions are different; and developing the exposed photosensitive layer to form vias and/or cavities having different depths in the plurality of regions.

According to the embodiments, the method for manufacturing a semiconductor device for reducing a production cost and a manufacturing time and reducing manufacturing process errors may be provided.

The effects of the present disclosure are not limited to the above-described effects, and may be expanded in various ways in the range of the ideas and the areas of the present disclosure.

### BRIEF DESCRIPTION OF THE DRAWINGS

FIG. 1 shows a cross-sectional view of a semiconductor device according to an embodiment.

FIG. 2 and FIG. 3 show cross-sectional views according to a method for manufacturing a semiconductor device according to an embodiment.

FIG. 4 shows a flowchart of a method for manufacturing a semiconductor device according to an embodiment.

FIG. 5 shows an example of a calibration curve related to a method for manufacturing a semiconductor device according to an embodiment.

FIG. 6 to FIG. 12 show cross-sectional views according to a method for manufacturing a semiconductor device according to an embodiment.

### DETAILED DESCRIPTION

The present disclosure will be described more fully hereinafter with reference to the accompanying drawings, in which embodiments of the disclosure are shown. As those skilled in the art would realize, the described embodiments may be modified in various different ways, all without departing from the spirit or scope of the present disclosure.

Parts that are irrelevant to the description will be omitted to clearly describe the present disclosure, and the same elements will be designated by the same reference numerals throughout the specification.

The accompanying drawings are provided only in order to allow embodiments disclosed in the present specification to be easily understood and are not to be interpreted as limiting the spirit disclosed in the present specification, and it is to be understood that the present disclosure includes all modifications, equivalents, and substitutions without departing from the scope and spirit of the present disclosure.

The size and thickness of each configuration shown in the drawings are arbitrarily shown for better understanding and ease of description, but the present disclosure is not limited thereto. In the drawings, the thickness of layers, films, panels, regions, etc., are enlarged for clarity. The thicknesses of some layers and areas are exaggerated for convenience of explanation.

It will be understood that when an element such as a layer, film, region, or substrate is referred to as being “on” another element, it can be directly on the other element or intervening elements may also be present. In contrast, when an element is referred to as being “directly on” another element, there are no intervening elements present. The word “on” or “above” means positioned on or below the object portion, and does not necessarily mean positioned on the upper side of the object portion based on a gravitational direction.

Unless explicitly described to the contrary, the word “comprise”, and variations such as “comprises” or “comprising”, will be understood to imply the inclusion of stated elements but not the exclusion of any other elements.

The phrase “in a plan view” means viewing an object portion from the top, and the phrase “in a cross-sectional view” means viewing a cross-section of which the object portion is perpendicularly cut from the side.

When it is described that a part is “connected” to another part, the part may be “directly connected” to the other element, may be “connected” to the other part through a third part, or may be connected to the other part physically or electrically, and they may be referred to by different titles depending on positions or functions, but respective portions that are substantially integrated into one body may be connected to each other.

Various embodiments and variations will now be described with reference to accompanying drawings.

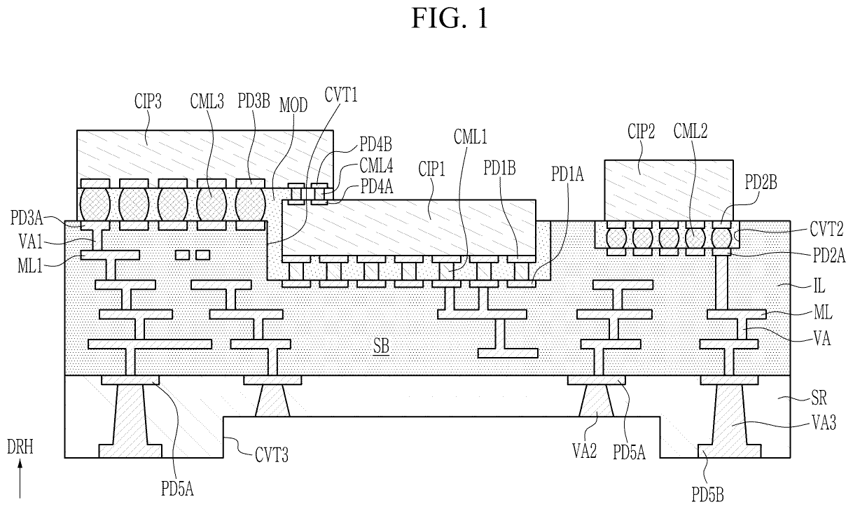

A semiconductor device according to an embodiment will now be described with reference to FIG. 1

FIG. 1 shows a cross-sectional view on a semiconductor device according to an embodiment.

Referring to FIG. 1, the semiconductor device may include a substrate SB including wiring layers ML and ML1 and vias VA and VA1 buried in an insulating layer IL, chips CIP1, CIP2, and CIP3 mounted on the substrate SB, and a protection layer SR covering a surface of the substrate SB.

The chips CIP1, CIP2, and CIP3 may be mounted on the insulating layer IL in a height direction DRH, and the protection layer SR may be disposed below the insulating layer IL, however the embodiment is not limited thereto.

The insulating layer IL of the substrate SB may have a first cavity CVT1 and a second cavity CVT2 with different depths.

The insulating layer IL may include a photosensitive material. The insulating layer IL may include an organic material such as a photo-imageable dielectric (PID) material. The photo-imageable dielectric material may, for example, include at least one of photosensitive polyimide, polybenzooxazole, phenol-based polymer, and benzocyclobutene-based polymer; however the embodiment is not limited thereto. The insulating layer IL may be formed by stacking layers, and the layers of the insulating layer IL may include a same material, and an interface between adjacent layers may not be distinguishable.

The first chip CIP1 may be mounted in the first cavity CVT1 of the insulating layer IL, the second chip CIP2 may be mounted in the second cavity CVT2 of the insulating layer IL, and the third chip CIP3 may be mounted on the insulating layer IL.

The chips CIP1, CIP2, and CIP3 may be semiconductor chips.

A plurality of pad layers PD1A, PD2A, and PD3A may be disposed in the insulating layer IL of the substrate SB. Upper surfaces of the pad layers PD1A, PD2A, and PD3A may not be covered by the insulating layer IL to be exposed.

The first chip CIP1 may be electrically connected to a wiring structure of the substrate SB including the wiring layers ML and ML1 and the vias VA and VA1 through pad layers PD1A in the first cavity CVT1 of the substrate SB, pad layers PD1B attached to the first chip CIP1, and first connection layers CML1 between the pad layers PD1A and the pad layers PD1B.

The second chip CIP2 may be electrically connected to the wiring structure of the substrate SB through pad layers PD2A disposed in the second cavity CVT2 of the substrate SB, pad layers PD2B attached to the second chip CIP2, and second connection layers CML2 between the pad layers PD2A and the pad layers PD2B.

The third chip CIP3 may be electrically connected to the wiring structure of the substrate SB through pad layers PD3A of the substrate SB, pad layers PD3B attached to the third chip CIP3, and third connection layers CML3 between the pad layers PD3A and the pad layers PD3B. The first chip CIP1 may be electrically connected to the third chip CIP3 through pad layers PD4A attached to the first chip CIP1, pad layers PD4B attached to the third chip CIP3, and fourth connection layers CML4 between the pad layers PD4A and pad layers PD4B.

The connection layers CML1, CML2, CML3, and CML4 may include solder materials. The solder materials may include, for example, tin, bismuth, lead, silver, or alloys thereof, however the embodiment is not limited thereto.

At least some of the pad layers PD3A of the substrate SB may be connected to the first wiring layer ML1 through the first via VA1.

At least some of the pad layers PD1A and PD2A of the substrate SB may be connected to the wiring layers ML through the vias VA.

A molding layer MOD may be in a space among the substrate SB and the chips CIP1, CIP2, and CIP3. The molding layer MOD may include an adhesive insulating film such as an Ajinomoto build up film (ABF) and may include an insulating polymer such as an epoxy-based polymer; however, the embodiment is not limited thereto.

A plurality of pad layers PD5A may be disposed on a lower surface of the substrate SB. The pad layers PD5A may be disposed on a lower portion of the insulating layer IL, and may be connected to the wiring layers ML through the vias VA.

The protection layer SR may protect the insulating layer IL and the pad layers PD5A. The protection layer SR may have photosensitivity. The protection layer SR may include or be a solder resist.

The protection layer SR may have a cavity CVT3, and vias VA2 and VA3 and pad layers PD5B may be disposed in the protection layer SR.

The vias VA2 in the protection layer SR may be connected to some of the pad layers PD5A disposed on the lower surface of the substrate SB. The pad layers PD5B in the protection layer SR may be connected to some of the pad layers PD5A disposed on the lower surface of the substrate SB through the vias VA3.

The vias VA2 and the pad layers PD5B in the protection layer SR may electrically connect external elements to the substrate SB.

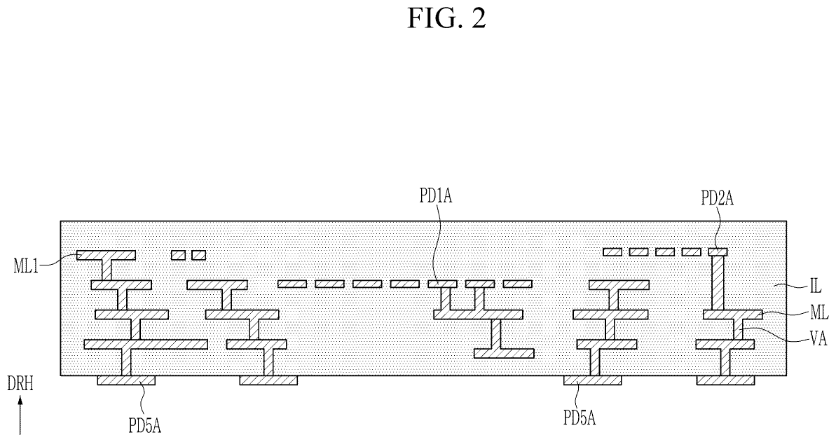

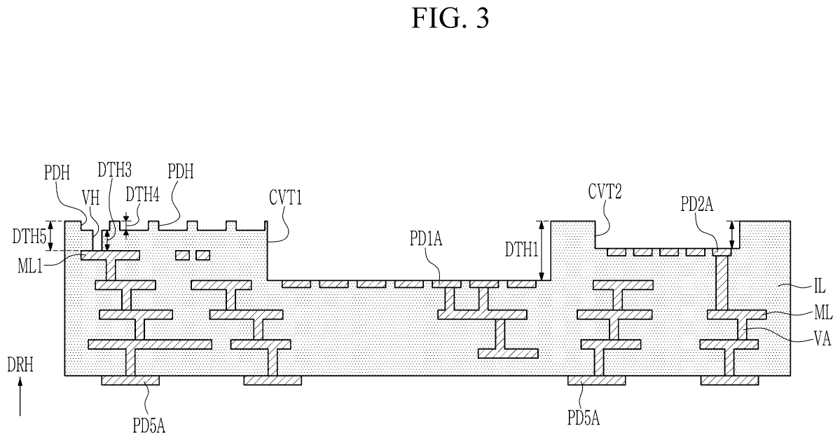

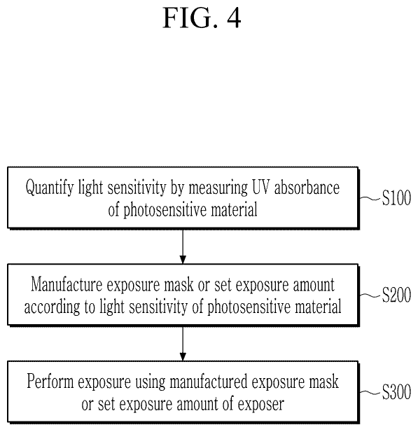

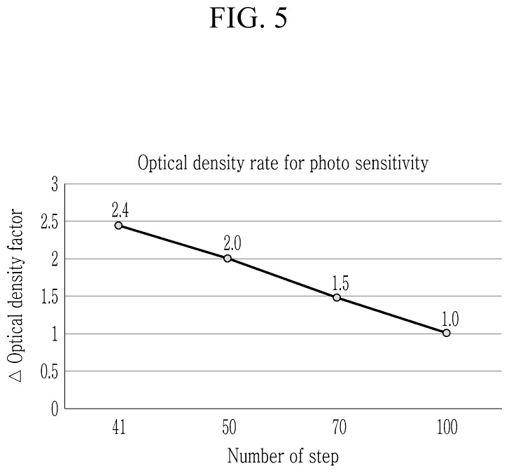

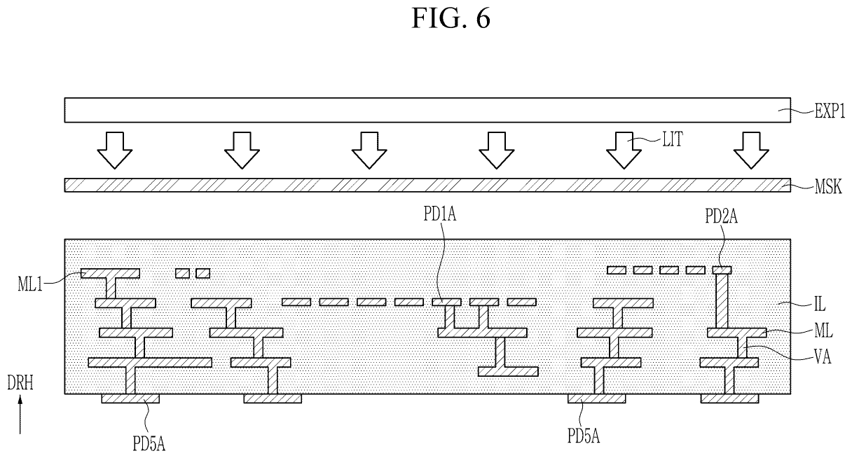

A method for manufacturing a semiconductor device according to an embodiment will now be described with reference to FIG. 2 to FIG. 12 together with FIG. 1. FIG. 2 and FIG. 3 show cross-sectional views according to a method for manufacturing a semiconductor device according to an embodiment, FIG. 4 shows a flowchart of a method for manufacturing a semiconductor device according to an embodiment, FIG. 5 shows an example of a calibration curve related to a method for manufacturing a semiconductor device according to an embodiment, and FIG. 6 to FIG. 12 show cross-sectional views according to a method for manufacturing a semiconductor device according to an embodiment.

Referring to FIG. 2, the wiring layers ML and ML1 and the vias VA and VA1 may be formed to be buried in the insulating layer IL. The insulating layer IL may be covered on the pad layers PD1A in the first cavity CVT1 to be formed later and the pad layers PD2A in the second cavity CVT2 to be formed later so the pad layers PD1A and PD2A may be buried in the insulating layer IL. The pad layers PD1A in the first cavity CVT1 and the pad layers PD2A in the second cavity CVT2 may have different depths to each other in the height direction DRH. Pad layers PD5A may be formed below the insulating layer IL.

Referring to FIG. 3, the first cavity CVT1 exposing the pad layers PD1A, the second cavity CVT2 exposing the pad layers PD2A, the via hole VH exposing the first wiring layer ML1 of the wiring layers ML and ML1, and pad holes PDH on a position where the pad layers PD3A will be formed may be simultaneously formed in the insulating layer IL.

The first cavity CVT1 may have a first depth DTH1, and the second cavity CVT2 may have a second depth DTH2. The first depth DTH1 may be different from the second depth DTH2. The first depth DTH1 may be greater than the second depth DTH2.

The via hole VH may have a third depth DTH3, and the pad holes PDH may have a fourth depth DTH4. The third depth DTH3 may be different from the fourth depth DTH4, the third depth DTH3 may be greater than the fourth depth DTH4, and the third depth DTH3 may be less than the second depth DTH2. A portion where the first via VA1 and the pad layer PD3A connected to the first wiring layer ML1 through the first via VA1 will be formed may have a fifth depth DTH5 that is a sum of the third depth DTH3 and the fourth depth DTH4.

A method for simultaneously forming a first cavity CVT1, a second cavity CVT2, a via hole VH, and pad holes PDH in the insulating layer IL according to the method for manufacturing a semiconductor device according to an embodiment will now be described with reference to FIG. 4 to FIG. 6.

Referring to FIG. 4, photosensitivity of a material forming the insulating layer IL may be quantified by measuring absorbance that is the characteristic of the material forming the insulating layer IL having photosensitivity (S100).

In detail, photosensitivity on the insulating layer IL which is a photosensitive layer may be quantified by measuring the characteristic of the insulating layer IL which has photosensitivity, that is, absorbance that is the characteristic of the photosensitive layer, and analyzing the measured absorbance using a calibration curve. For example, the photosensitivity may represent degrees for the photosensitive layer to absorb light or depths by which light reaches the photosensitive layer. That is, degrees to which the insulating layer IL is photosensitized may be quantified depending on light energy which reaches the insulating layer IL that is a photosensitive layer.

FIG. 5 shows an example of the calibration curve. In detail, FIG. 5 shows a calibration curve graph of absorbance of a photosensitive layer in which an absorption peak wavelength of a photoinitiator included in the photosensitive layer is about 365 nm.

As shown in FIG. 5, photosensitivity of the insulating layer IL that is a photosensitive layer may be quantified by measuring absorbance of the photosensitive layer and analyzing the measured absorbance using a calibration curve.

Referring to FIG. 4, an exposure mask may be manufactured or exposure amounts of an exposer may be set to adjust light energy applied to positions of the insulating layer IL where the cavities CVT1 and CVT2, via hole VH, and pad hole PDH with various depths DTH1, DTH2, DTH3, DTH4, and DTH5 will be formed based on the quantified photosensitivity results of the material forming the insulating layer IL (S200).

The insulating layer IL may be exposed using the mask manufactured or using the set exposure amounts of the exposer at the step S200 (S300).

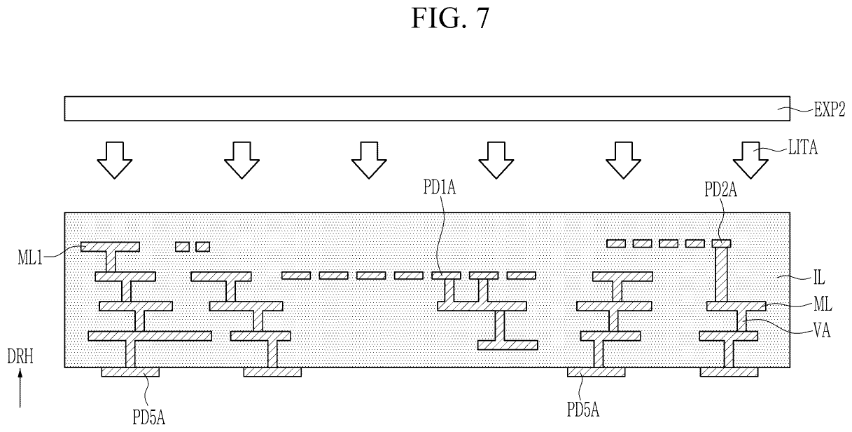

The step S300 will now be described with reference to FIG. 6 and FIG. 7.

Referring to FIG. 6, the insulating layer IL may be exposed using the mask MSK manufactured at the step S200. In this instance, a first exposer EXP1 may be used, and energy of light LIT irradiated from the first exposer EXP1 may be the same regardless of positions.

The mask MSK may have different light transmittance values in regions that correspond to the positions of the insulating layer IL, where the cavities CVT1 and CVT2, the via hole VH, and the pad hole PDH with various depths DTH1, DTH2, DTH3, DTH4, and DTH5 will be formed.

The light LIT with the same energy irradiated from the first exposer EXP1 may reach the insulating layer IL through the exposure mask MSK controlling light energy applied to the positions of the insulating layer IL and having various values of light transmittance depending on the positions so the reaching light energy may be different depending on the positions of the insulating layer IL.

For example, in case that the insulating layer IL has positive photosensitivity, the light energy applied to the insulating layer IL may be reduced in order of the position where the first cavity CVT1 with the first depth DTH1 is formed, the position where the second cavity CVT2 with the second depth DTH2 is formed, the position where the via hole VH with the third depth DTH3 is formed, and the position where the pad hole PDH with the fourth depth DTH4 is formed. In case that the insulating layer IL has negative photosensitivity, the light energy applied to the insulating layer IL may be increased in order of the position where the first cavity CVT1 with the first depth DTH1 is formed, the position where the second cavity CVT2 with the second depth DTH2 is formed, the position where the via hole VH with the third depth DTH3 is formed, and the position where the pad hole PDH with the fourth depth DTH4 is formed.

The cavities CVT1 and CVT2, the via hole VH, and the pad hole PDH with various values of depths DTH1, DTH2, DTH3, DTH4, and DTH5 may be simultaneously formed in the insulating layer IL by developing the exposed insulating layer IL using the mask MSK manufactured at the step S200.

Referring to FIG. 7, the insulating layer IL may be exposed to the light using the set exposure amounts at the step S200 (S300). In this instance, a second exposer EXP2 may be used, and the energy of light LITA irradiated from the second exposer EXP2 may have predetermined values depending on positions.

The second exposer EXP2 may be a direct imaging exposer. The second exposer EXP2 may irradiate predetermined light LITA of energy depending on the positions of the insulating layer IL set at the step S200. By this, the reaching light energy may vary depending on the positions of the insulating layer IL.

As described above, for example, in case that the insulating layer IL has positive photosensitivity, the light energy applied to the insulating layer IL may be reduced in order of the position where the first cavity CVT1 with the first depth DTH1 is formed, the position where the second cavity CVT2 with the second depth DTH2 is formed, the position where the via hole VH with the third depth DTH3 is formed, and the position where the pad hole PDH with the fourth depth DTH4 is formed. In case that the insulating layer IL has negative photosensitivity, the light energy applied to the insulating layer IL may be increased in order of the position where the first cavity CVT1 with the first depth DTH1 is formed, the position where the second cavity CVT2 with the second depth DTH2 is formed, the position where the via hole VH with the third depth DTH3 is formed, and the position where the pad hole PDH with the fourth depth DTH4 is formed.

The insulating layer IL is exposed to light using the light LITA having the set energy depending on the positions of the insulating layer IL at the step S200 and the exposed insulating layer IL is developed so the cavities CVT1 and CVT2, the via hole VH, and the pad hole PDH with various depths DTH1, DTH2, DTH3, DTH4, and DTH5 may be simultaneously formed in the insulating layer IL.

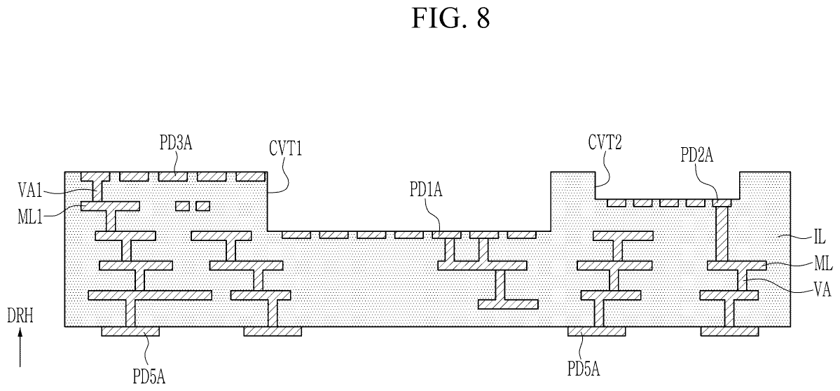

Referring to FIG. 8, the first via VA1 may be formed in the via hole VH, and the pad layers PD3A may be formed in the pad hole PDH.

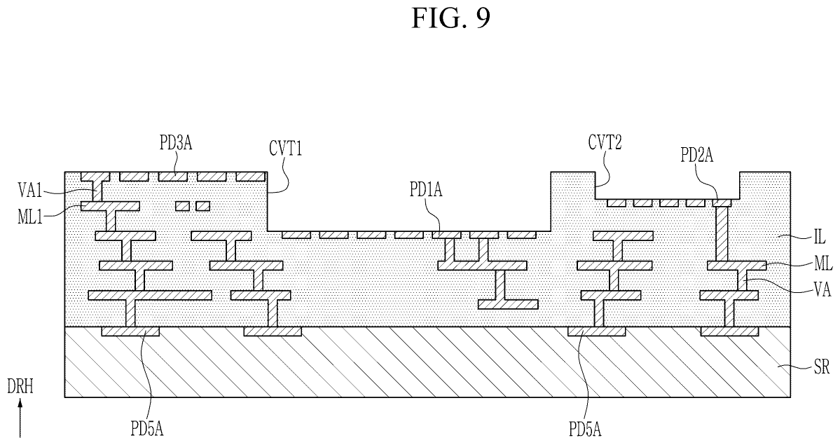

Referring to FIG. 9, the protection layer SR may be stacked below the insulating layer IL to cover the pad layers PD5A. The protection layer SR may have photosensitivity. The protection layer SR may include or be a solder resist.

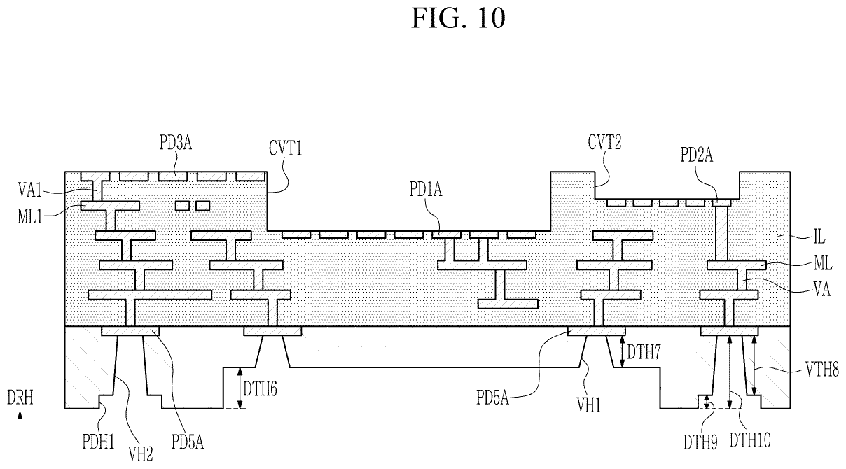

Referring to FIG. 10, the third cavity CVT3, the first via hole VH1, the second via hole VH2, and the first pad hole PDH1 may be simultaneously formed in the protection layer SR. The second via VA2 may be formed in the first via hole VH1, the third via VA3 may be formed in the second via hole VH2, and the pad layer PD5B may be formed in the first pad hole PDH1.

The third cavity CVT3 may have a sixth depth DTH6, the first via hole VH1 may have a seventh depth DTH7, the second via hole VH2 may have an eighth depth DTH8, and the first pad hole PDH1 may have a ninth depth DTH9. The sixth depth DTH6, the seventh depth DTH7, the eighth depth DTH8, and the ninth depth DTH9 may be different from each other.

A region in which the third via VA3 connected to the pad layers PD5A disposed on a lower surface of the insulating layer IL and the pad layer PD5B will be formed may have a tenth depth DTH10 that is the sum of the eighth depth DTH8 and the ninth depth DTH9.

The method for simultaneously forming the third cavity CVT3, the first via hole VH1, the second via hole VH2, and the first pad hole PDH1 with different depths DTH6, DTH7, DTH8, and DTH9 in the protection layer SR is similar to the method for simultaneously forming the first cavity CVT1, the second cavity CVT2, the via hole VH, and the pad holes PDH in the insulating layer IL described with reference to FIG. 4 to FIG. 6.

Photosensitivity of a material forming the protection layer SR may be quantified measuring absorbance that is the characteristic of the protection layer SR (S100), the exposure mask may be manufactured or the exposure amounts of the exposer may be set to adjust light energy applied to the positions of the protection layer SR where the cavity CVT3, the via holes VH1 and VH2 and the pad hole PDH1 with various depths DTH6, DTH7, DTH8, DTH9, and DTH10 will be formed based on the quantified photosensitivity result of the protection layer SR (S200), the protection layer SR may be exposed using the exposure mask manufactured at the step S200 or using the set exposure amounts at the step S200 (S300).

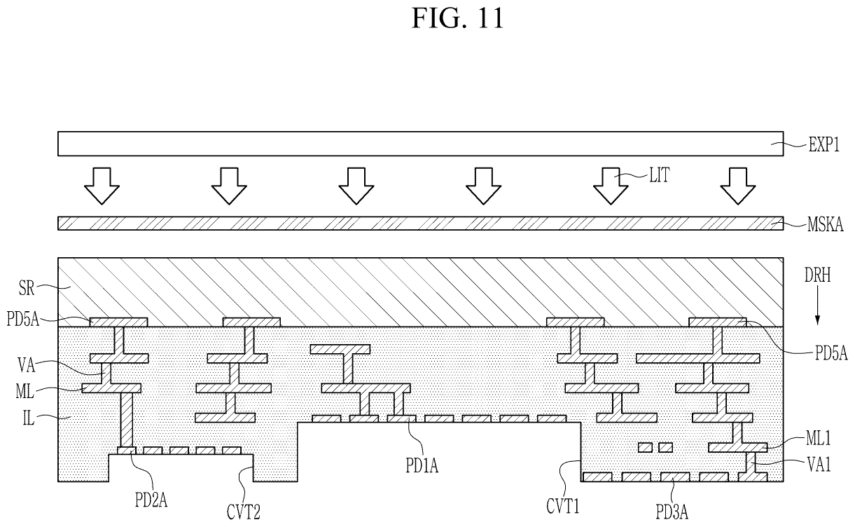

Referring to FIG. 11, the protection layer SR may be exposed using the mask MSKA for the protection layer SR manufactured at the step S200. In this instance, the first exposer EXP1 may be used, and the energy of light LIT irradiated from the first exposer EXP1 may be the same regardless of the positions.

The light LIT of the same energy irradiated from the first exposer EXP1 reaches the protection layer SR through the exposure mask MSKA for adjusting the light energy applied to the positions of the protection layer SR so the reaching light energy may be different depending on the positions of the protection layer SR.

The cavity CVT3, the via holes VH1 and VH2, and the pad hole PDH1 with various depths DTH6, DTH7, DTH8, DTH9, and DTH10 may be formed in the protection layer SR, by developing the protection layer SR exposed by the light energy adjusted depending on the positions using the exposure mask MSKA.

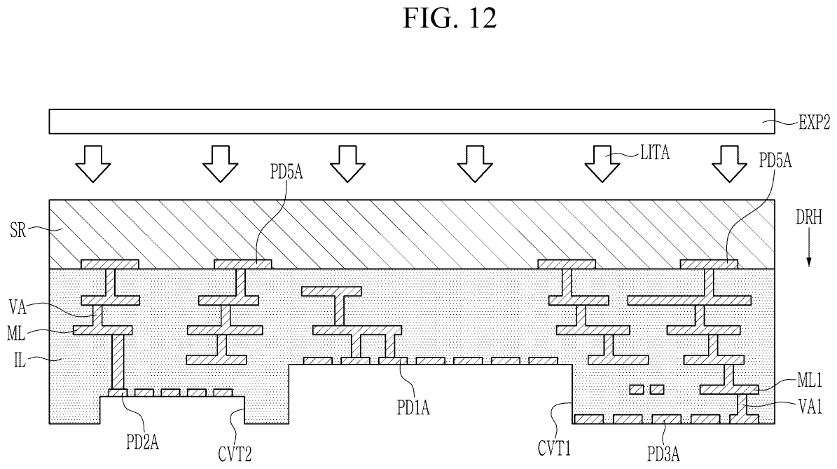

Referring to FIG. 12, the protection layer SR may be exposed using the exposure amounts set at the step S200 (S300). In this instance, the second exposer EXP2 may be used, and the energy of light LITA irradiated from the second exposer EXP2 may have the set values depending on the positions.

The second exposer EXP2 may be a direct imaging exposer. The second exposer EXP2 may irradiate the set light LITA of energy depending on the positions of the protection layer SR at the step S200. By this, the reaching light energy may be different depending on the positions of the protection layer SR.

The cavity CVT3, the via holes VH1 and VH2, and the pad hole PDH1 with various depths DTH6, DTH7, DTH8, DTH9, and DTH10 may be formed in the protection layer SR by developing the exposed the protection layer SR using the set light LITA of energy depending on the positions of the protection layer SR at the step S200.

The vias VA2 and VA3 are formed in the via holes VH1 and VH2 of the protection layer SR and the pad layers PD5B are formed in the pad holes PDH1 of the protection layer SR to form the semiconductor device of FIG. 1.

According to the method for manufacturing a semiconductor device according to the embodiment, absorbance that is the characteristic of a material forming the photosensitive layer may be measured to quantify photosensitivity of the photosensitive layer (S100), the exposure mask may be manufactured or the exposure amounts of the exposer may be set to adjust the light energy applied to the positions of the photosensitive layer based on the quantified photosensitivity result of the material forming the photosensitive layer (S200), and the exposure step is performed using the mask manufactured at the step S200 or using the set exposure amount at the step S200 (S300), so the cavities and holes with various depths of the photosensitive layer may be formed by one exposure process.

As described above, the cavities CVT1 and CVT2, the via hole VH, and the pad hole PDH with various depths DTH1, DTH2, DTH3, DTH4, and DTH5 may be simultaneously formed in the insulating layer IL with photosensitivity, and the cavity CVT3, the via holes VH1 and VH2, and the pad hole PDH1 with various depths DTH6, DTH7, DTH8, DTH9, and DTH10 may be formed in the protection layer SR with photosensitivity.

According to the method for manufacturing a semiconductor device according to the embodiment, the production cost may be reduced, the manufacturing time may be shortened, and generation of misalignment may be prevented to reduce the process errors by forming the cavities and holes with various depths through the exposure process.

While this disclosure has been described in connection with what is presently considered to be practical embodiments, it is to be understood that the disclosure is not limited to the disclosed embodiments, but, on the contrary, is intended to cover various modifications and equivalent arrangements included within the spirit and scope of the appended claims.

### DESCRIPTION OF SYMBOLS

SB: substrate
IL: insulating layer
CIP1, CIP2, CIP3: chip
CVT1, CVT2, CVT3: cavity
ML, ML1: wiring layer
VA, VA1, VA2, VA3: via
SR: protection layer
PD1A, PD1B, PD2A, PD2B, PD3A, PD3B, PD4A, PD4B, PD5A, PD5B: pad layer
EXP1, EXP2: exposer
MSK, MSKA: mask
CML1, CML2, CML3: connection layer

What is claimed is:

1. A method for manufacturing a semiconductor device comprising:
measuring absorbance of a photosensitive material and quantifying photosensitivity of the photosensitive material;
manufacturing an exposure mask based on the photosensitivity of the photosensitive material;
stacking a photosensitive layer made of the photosensitive material; and
exposing the photosensitive layer using the exposure mask.

2. The method of claim 1, wherein
the quantifying of photosensitivity includes analyzing the measured absorbance using a calibration curve.

3. The method of claim 1, wherein
the exposing is performed by using a first exposer irradiating predetermined light of energy.

4. The method of claim 1, wherein
the exposure mask includes a plurality of regions with different light transmittance values.

5. The method of claim 1, further comprising
developing the exposed photosensitive layer.

6. The method of claim 5, wherein
after developing the exposed photosensitive layer, the photosensitive layer is formed to have a first cavity with a first depth in a first region, a second cavity with a second depth in a second region, a via hole with a third depth in a third region, and a pad hole with a fourth depth in a fourth region, and
the first depth, the second depth, the third depth, and the fourth depth are different from each other.

7. The method of claim 6, wherein
the first depth is greater than the second depth,
the second depth is greater than the third depth, and
the third depth is greater than the fourth depth.

8. The method of claim 7, wherein
the photosensitive layer has positive photosensitivity, and
the light transmittance values of the exposure mask are reduced in order of a fifth region of the exposure mask corresponding to the first region, a sixth region of the exposure mask corresponding to the second region, a seventh region of the exposure mask corresponding to the third region, and an eighth region of the exposure mask corresponding to the fourth region.

9. The method of claim 7, wherein
the photosensitive layer has negative photosensitivity, and
the light transmittance values of the exposure mask are increased in order of a fifth region of the exposure mask corresponding to the first region, a sixth region of the exposure mask corresponding to the second region, a seventh region of the exposure mask corresponding to the third region, and an eighth region of the exposure mask corresponding to the fourth region.

10. The method of claim 6, further comprising
forming a via in the via hole, and forming a pad layer in the pad hole.

11. A method for manufacturing a semiconductor device comprising:
measuring absorbance of a photosensitive material and quantifying photosensitivity of the photosensitive material;
stacking a photosensitive layer made of the photosensitive material;
based on the photosensitivity of the photosensitive material, setting exposure amounts depending on positions of the photosensitive layer; and
exposing the photosensitive layer using the set exposure amounts.

12. The method of claim 11, wherein
the quantifying of photosensitivity includes analyzing the measured absorbance using a calibration curve.

13. The method of claim 11, wherein
the exposing is performed by using a second exposer, and
the second exposer is a direct imaging exposer.

14. The method of claim 11, further comprising
developing the exposed photosensitive layer.

15. The method of claim 14, wherein
after developing the exposed photosensitive layer, the photosensitive layer is formed to have a first cavity with a first depth in a first region, a second cavity with a second depth in a second region, a via hole with a third depth in a third region, and a pad hole with a fourth depth in a fourth region, and
the first depth, the second depth, the third depth, and the fourth depth are different from each other.

16. The method of claim 15, wherein
the first depth is greater than the second depth,
the second depth is greater than the third depth, and
the third depth is greater than the fourth depth.

17. The method of claim 16, wherein
the photosensitive layer has positive photosensitivity, and
the set exposure amounts decrease in order of the first region, the second region, the third region, and the fourth region.

18. The method of claim 16, wherein
the photosensitive layer has negative photosensitivity, and
the set exposure amounts increase in order of the first region, the second region, the third region, and the fourth region.

19. The method of claim 15, further comprising
forming a via in the via hole, and forming a pad layer in the pad hole.

20. A method for manufacturing a semiconductor device comprising:
measuring absorbance of a photosensitive material and quantifying photosensitivity of the photosensitive material;
forming a photosensitive layer made of the photosensitive material;
simultaneously exposing a plurality of regions of the photosensitive layer, such that, based on the photosensitivity of the photosensitive material, light energy irradiated on the plurality of regions are different; and
developing the exposed photosensitive layer to form vias and/or cavities having different depths in the plurality of regions.
